(19) United States
(12) Patent Application Publication
(10) Pub. No.: US 2005/0093046 A1
(43) Pub. Date: May 5, 2005

(54) Plurality of capacitors employing holding layer patterns and method of fabricating the same

(76) Inventor: Tae-Hyuk Ahn, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/971,022

(22) Filed: Oct. 25, 2004

(30) Foreign Application Priority Data
Nov. 3, 2003 (KR) 2003-77414

(51) Int. Cl. G02F 1/1347; H01L 29/94

(52) U.S. Cl. 257/296; 361/311

(57) ABSTRACT

A plurality of capacitors employing holding layer patterns, and a method of fabricating the same, the plurality of capacitors including a plurality of cylinder-shaped lower plates repeatedly aligned in two dimensions. Holding layer patterns are located between the uppermost portions and the lowermost portions of the plurality of lower plates, and connect the adjacent side walls of the plurality of lower plates. An upper plate fills the spaces inside the plurality of lower plates and the spaces between the side walls of the plurality of lower plates. A capacitor dielectric layer is interposed between the plurality of lower plates and the upper plate, and insulates the lower plates and the upper plate.

### CROSS-REFERENCE TO RELATED APPLICATION

A claim of priority is made to Korean Patent Application No. 2003-77414, filed on Nov. 3, 2003, the disclosure of which is hereby incorporated herein by reference in its entirety.

### BACKGROUND OF THE INVENTION

1. Field of the Invention

The present invention relates to a semiconductor substrate and a method of fabricating the same, and more particularly, to a plurality of capacitors employing holding layer patterns and a method of fabricating the same.

2. Description of the Related Art

Memory devices such as DRAM require a plurality of cell capacitors having sufficient capacitance in order to improve resistance to a particles and increase a refresh cycle. In order to realize a capacitor having sufficient capacitance, it is necessary to increase an overlap space between an upper plate and a lower plate, or decrease a thickness of a dielectric layer interposed between the upper plate and the lower plate. Further, in order to realize the capacitor, the dielectric layer should be formed of a material layer having a high dielectric constant.

Recently, in order to form a plurality of capacitors having sufficient capacitance, a method of increasing a height of the lower plates is widely employed. By increasing the height of the lower plates, the surface area of the lower plates can be increased. Accordingly, the overlap space between the upper plate and the lower plate is increased, and thus, the capacitance of the cell capacitor is increased.

However, with the increase of height of the lower plates, there often occurs a phenomenon that the lower plates fall down, and lean toward other adjacent lower plates. The phenomenon, which is called “leaning”, results in the lower plates being electrically connected, and causes a 2-bit failure.

As a result, there is a need for a plurality of capacitors having lower plates of increased height without leaning of the lower plates, and a method of fabricating the same.

### SUMMARY OF THE INVENTION

The present invention provides a plurality of capacitors having lower plates of increased height that are capable of exhibiting sufficient capacitance, without leaning of the lower plates.

Another object of the present invention is to provide a semiconductor device having a plurality of capacitors with lower plates of increased height that are capable of exhibiting sufficient capacitance without leaning of the lower plates.

A further object of the present invention is to provide a method of fabricating a plurality of capacitors having sufficient capacitance by increasing the height of lower plates, while preventing leaning of the lower plates during the fabrication process.

In accordance with an. exemplary embodiment, the present invention provides a plurality of capacitors employing holding layer patterns. The plurality of capacitors include a plurality of cylinder-shaped lower plates repeatedly aligned on a same plane in two dimensions. Holding layer patterns are located between uppermost portions and lowermost portions of the plurality of lower plates, and connect the adjacent side walls of the plurality of lower plates. An upper plate fills the spaces inside the plurality of lower plates and the spaces between the side walls thereof. A capacitor dielectric layer is interposed between the plurality of lower plates and the upper plate, and insulates the lower plates and the upper plate. As such, the holding layer patterns are located between the side walls of the lower plates to support the lower plates. As a result, the structure serves to avoid leaning of the lower plates.

The holding layer patterns are formed of a non-conductive material layer. The holding layer patterns may have a thickness of 100 Å to 1000 Å, and the non-conductive material layer may be a silicon nitride (SiN) layer or a silicon carbide (SiC) layer.

Each of the plurality of cylinder-shaped lower plates aligned in two dimensions may be aligned to have four adjacent lower plates. The holding layer patterns may individually connect each of the lower plates and the corresponding four adjacent lower plates.

The horizontal section of each of the plurality of cylinder-shaped lower plates is not limited to a circular shape. For example, the horizontal section of each of the plurality of cylinder-shaped lower plates may be an oval shape.

Further, each of the plurality of cylinder-shaped lower plates aligned in two dimensions may be aligned to have six adjacent lower plates. In this embodiment, each of the holding layer patterns may connect three adjacent lower plates together.

Each of the holding layer patterns may include a pair of elements, which are spaced and face each other. In this embodiment, each of the holding layer patterns may be a pair of etched spacers, the lower sides of which are wide and the upper sides of which are narrow. The etched spacers may have a height of 500 Å to 2000 Å.

In accordance with an exemplary embodiment, the present invention provides a semiconductor device having a plurality of capacitors employing holding layer patterns. The semiconductor device includes a semiconductor substrate. A plurality of cylinder-shaped lower plates are aligned repeatedly over the semiconductor substrate in two dimensions. Holding layer patterns are located between uppermost portions and lowermost portions of the plurality of lower plates, and connect the adjacent side walls of the plurality of lower plates. An upper plate fills the spaces inside the plurality of lower plates and the spaces between the side walls thereof. A capacitor dielectric layer is interposed between the plurality of lower plates and the upper plate, and insulates the lower plates and the upper plate.

Further, storage contact plugs may be interposed between the semiconductor substrate and each of the plurality of lower plates, and connect the semiconductor substrate and each of the plurality of lower plates, respectively.

In accordance with a further exemplary embodiment, the present invention provides a method of fabricating a plurality of capacitors employing holding layer patterns. The method includes preparing a semiconductor substrate having a lower insulating layer. A plurality of storage contact plugs repeatedly aligned in two dimensions are formed inside the lower insulating layer. An etch barrier layer and a lower sacrificial oxide layer are sequentially formed on the semiconductor substrate having the storage contact plugs. A holding layer having openings exposing the lower sacrificial oxide layer is formed on the lower sacrificial oxide layer. Herein, the centers of the respective openings are located above portions of the lower insulating layer that are surrounded by the storage contact plugs. An upper sacrificial oxide layer is formed over the semiconductor substrate having the holding layer with the openings. The upper sacrificial oxide layer, the holding layer, the lower sacrificial oxide layer, and the etch barrier layer are sequentially patterned using photolithography and etch processes, to form capacitor holes exposing the storage contact plugs and holding layer patterns. The holding layer patterns are exposed inside the capacitor holes. Then, lower plates covering the inner walls of the capacitor holes are formed, and the upper sacrificial oxide layer and the lower sacrificial oxide layer between the lower plates are sequentially removed. As the holding layer patterns support the lower plates, even though the upper sacrificial oxide layer and the lower sacrificial oxide layer between the lower plates are removed, falling-down of the lower plates can be avoided.

The formation of the holding layer having the openings may include forming a holding material layer on the lower sacrificial oxide layer. A photoresist layer is formed on the holding material layer, and the photoresist layer is patterned to form a photoresist pattern having openings exposing the holding material layer. The holding material layer is etched using the photoresist pattern as an etch mask.

The holding material layer may be formed of a non-conductive material layer having a low etch rate for wet etch recipes of the lower sacrificial oxide layer and the upper sacrificial oxide layer. The non-conductive material layer may be formed to have a thickness of 100 Å to 1000 Å, and may be an SiN or SiC layer.

The formation of the lower plates may include forming a lower plate conductive layer on the semiconductor substrate having the capacitor holes. A filling layer filling the capacitor holes is formed on the semiconductor substrate having the lower plate conductive layer, and the filling layer and the lower plate conductive layer are planarized until the top surface of the upper sacrificial oxide layer is exposed. Then, the filling layer filling the capacitor holes is removed.

In accordance with another exemplary embodiment, the present invention provides a method of fabricating a plurality of capacitors employing holding layer patterns. The method includes preparing a semiconductor substrate having a lower insulating layer. A plurality of storage contact plugs repeatedly aligned in two dimensions are formed inside the lower insulating layer. An etch barrier layer and a lower sacrificial oxide layer are sequentially formed on the semiconductor substrate having the storage contact plugs, and the lower sacrificial oxide layer is partially etched to form grooves repeatedly aligned in two dimensions. Herein, the centers of the respective grooves are located above portions of the lower insulating layer that are surrounded by the storage contact plugs. Then, spacers covering the inner walls of the grooves are formed. An upper sacrificial oxide layer is formed on the semiconductor substrate having the spacers. The upper sacrificial oxide layer, the spacers, the lower sacrificial oxide layer, and the etch barrier layer are sequentially patterned using photolithography and etch processes, to form capacitor holes exposing the storage contact plugs and holding layer patterns. Herein, the holding layer patterns are exposed inside the capacitor holes. Then, lower plates covering the inner walls of the capacitor holes are formed, and the upper sacrificial oxide layer and the lower sacrificial oxide layer between the lower plates are sequentially removed. As the holding layer patterns are formed of spacers having a wide lower side and a narrow upper side, it is easy to form a following capacitor dielectric layer and an upper plate between the lower plates. Thus, the height of the holding layer patterns can be increased.

The lower sacrificial oxide layer may be partially etched to a depth of 500 Å to 2000 Å.

The spacers may be formed of a non-conductive material layer having a low etch rate for wet etch recipes of the upper sacrificial oxide layer and the lower sacrificial oxide layer, and may be formed of an SiN or SiC layer.

### BRIEF DESCRIPTION OF THE DRAWINGS

The above and other features and advantages of the present invention will become more apparent to those of ordinary skill in the art from the detailed description that follows, with reference to the accompanying drawings, in which:

FIGS. 1A and 1B are top plan views respectively showing a holding layer having openings, and a plurality of lower plates to illustrate a method of fabricating a plurality of capacitors according to one embodiment of the present invention;

FIGS. 2A to 2I are sectional views illustrating a method of fabricating a plurality of capacitors according to one embodiment of the present invention;

FIGS. 3A and 3B are top plan views respectively showing a holding layer having openings, and a plurality of lower plates to illustrate another plurality of capacitors fabricated according to processing sequences of an embodiment of the present invention;

FIGS. 4A and 4B are top plan views respectively showing a holding layer having openings, and a plurality of lower plates to illustrate a further plurality of capacitors fabricated according to processing sequences of an embodiment of the present invention;

FIGS. 5A and 5B are top plan views respectively showing a lower sacrificial oxide layer having spacers, and a plurality of lower plates to illustrate a method of fabricating a plurality of capacitors according to another embodiment of the present invention;

FIGS. 6A to 6G are sectional views illustrating a method of fabricating a plurality of capacitors according to another embodiment of the present invention; and

FIGS. 7 and 8 are top plan views showing a plurality of lower plates to respectively illustrate another plurality of capacitors fabricated according to processing sequences of another embodiment of the present invention.

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout the specification.

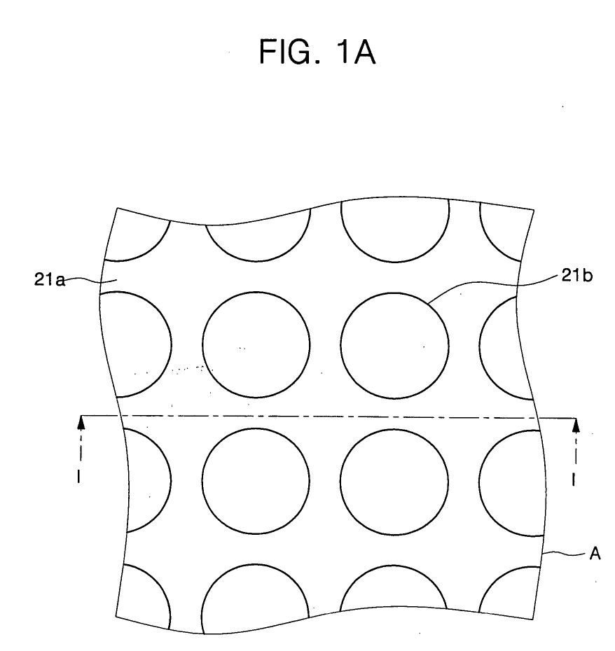

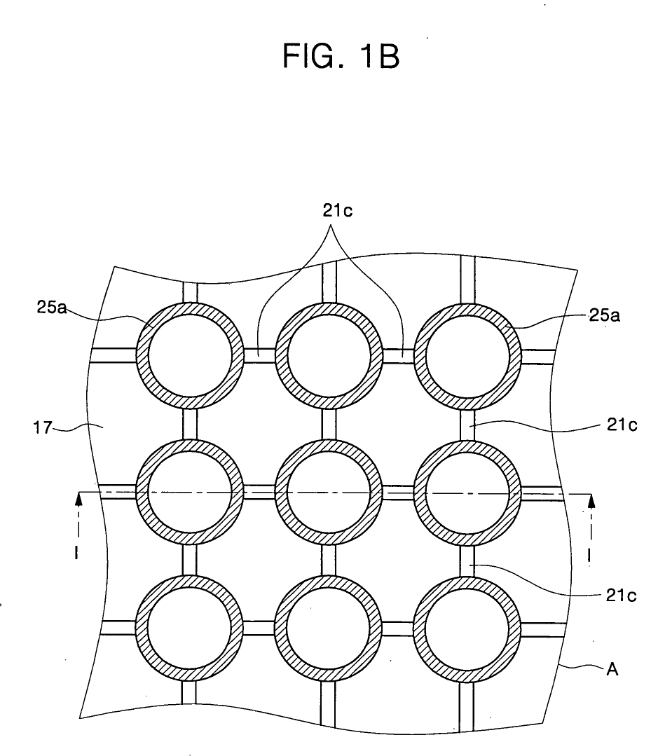

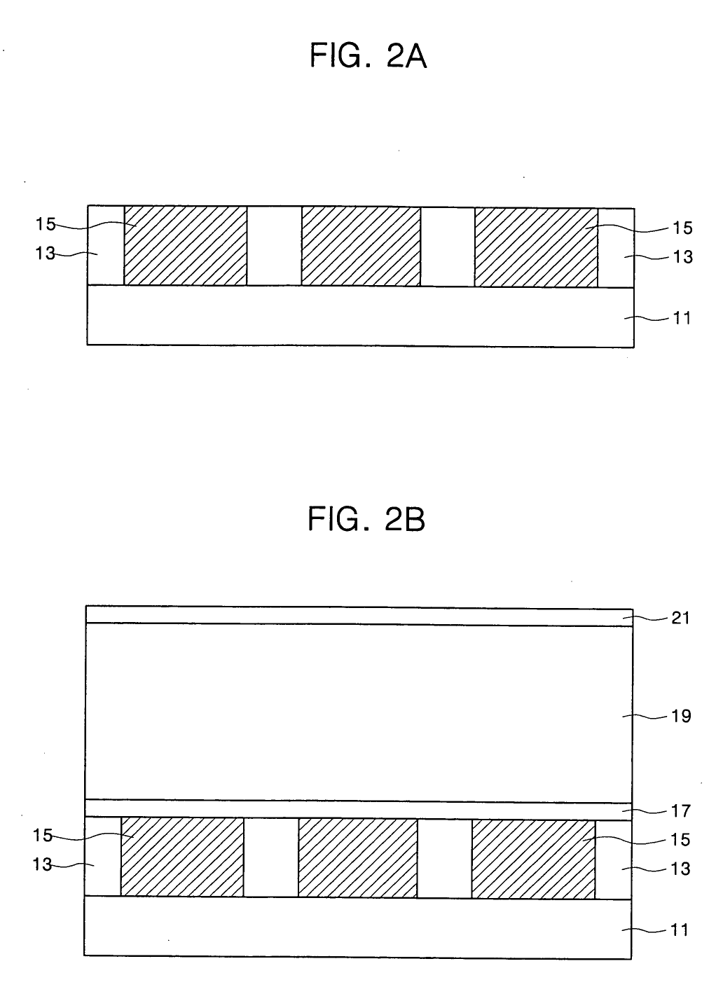

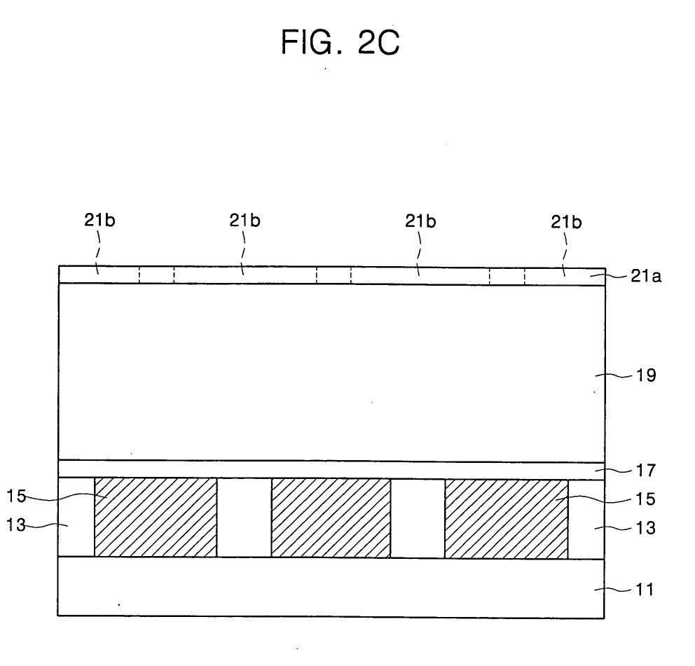

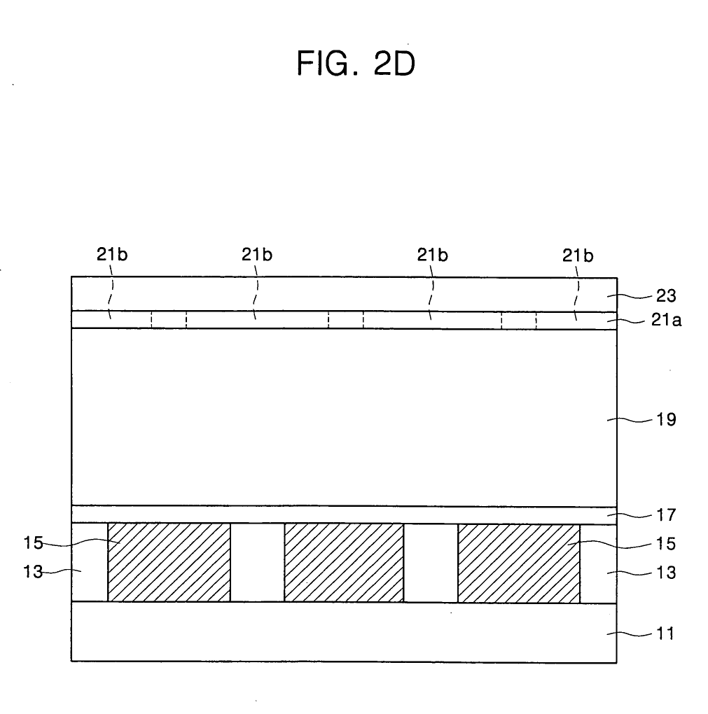

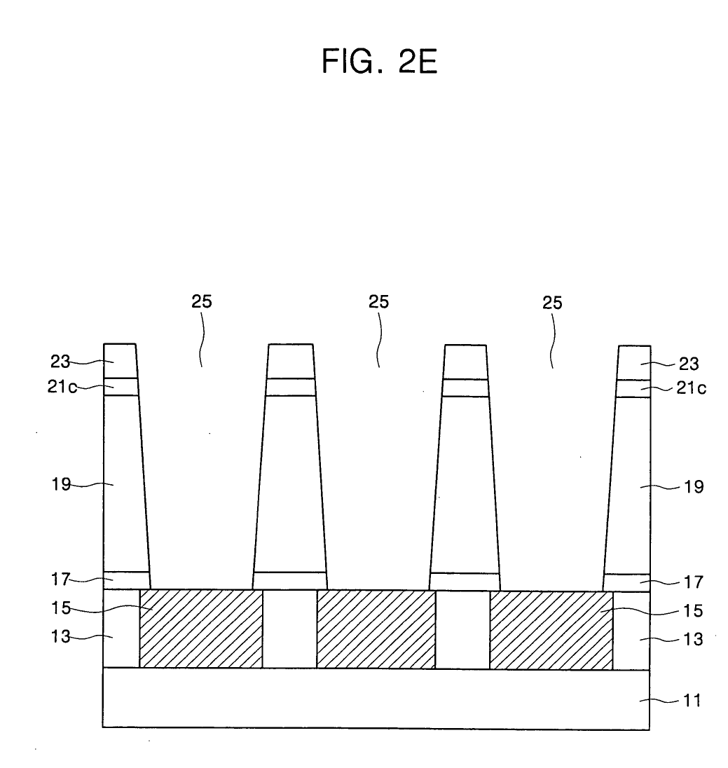

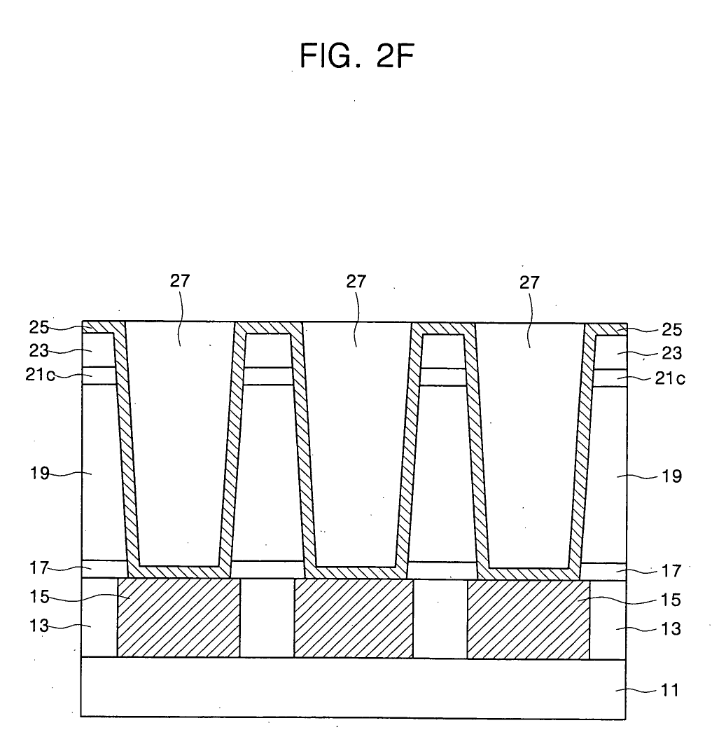

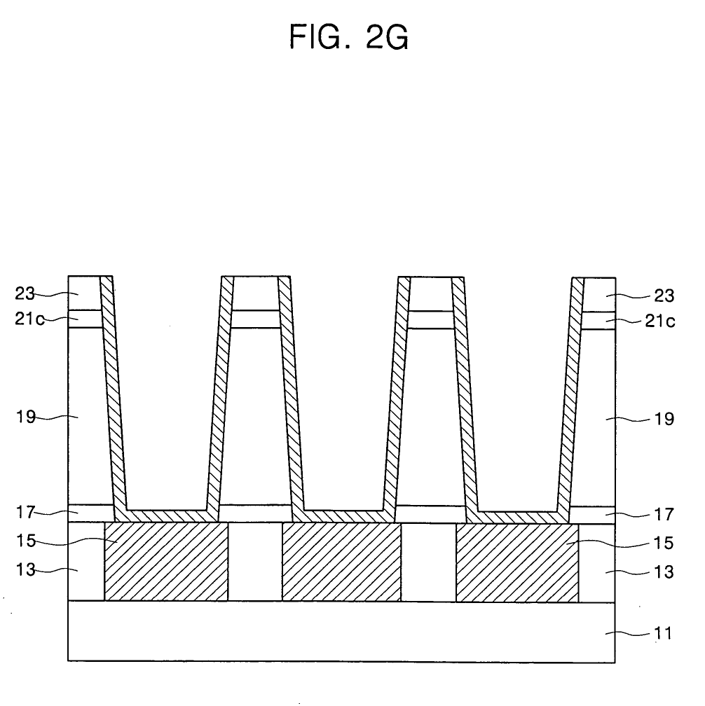

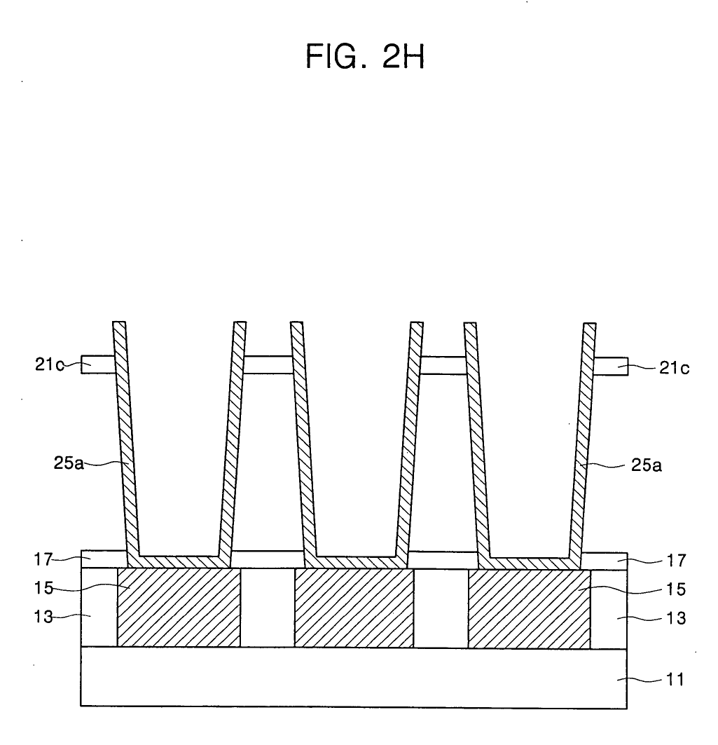

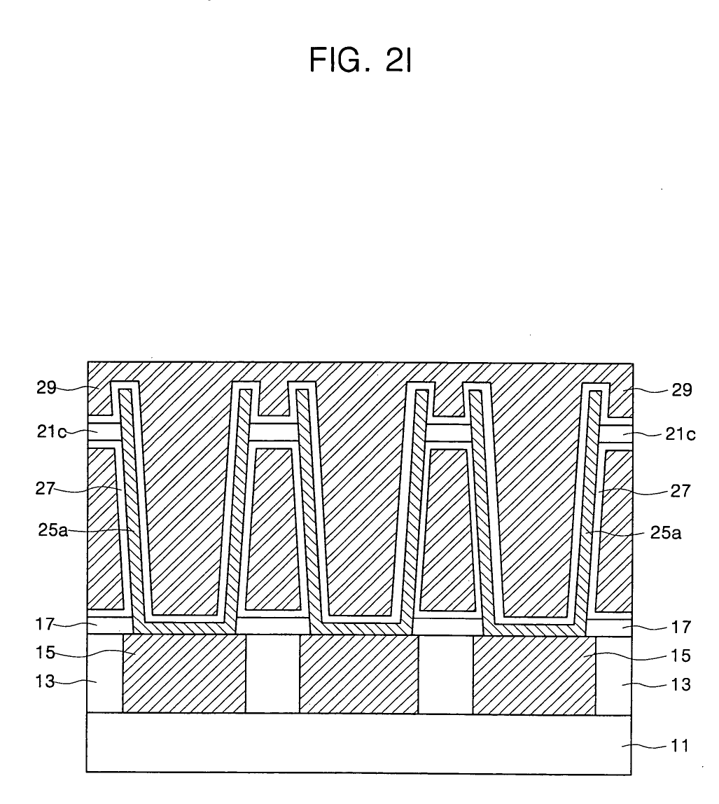

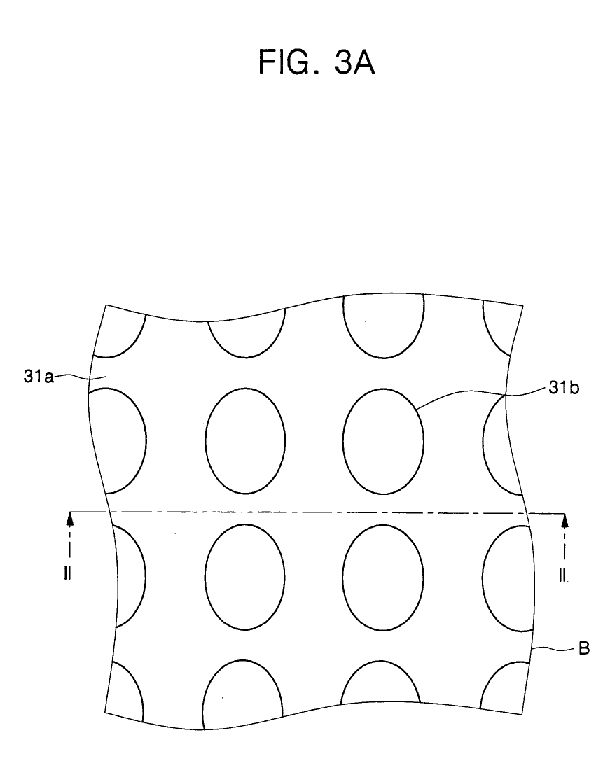

FIGS. 1A and 1B are top plan views respectively showing a holding layer having openings, and a plurality of lower plates to illustrate a method of fabricating a plurality of capacitors according to one embodiment of the present invention. FIGS. 2A to 2I are sectional views illustrating a method of fabricating a plurality of capacitors according to one embodiment of the present invention taken along the line I-I of FIGS. 1A and 1B. In FIGS. 1A and 1B, the reference letter “A” represents the same area on a semiconductor substrate.

Referring to FIGS. 1A, 1B, and 2A, a semiconductor substrate 11 having a lower insulating layer 13 is prepared. Transistors (not shown) and bit lines (not shown) may be formed on the semiconductor substrate 11. The lower insulating layer 13 electrically insulates the transistors and the bit lines from a plurality of capacitors to be formed thereon.

Storage contact plugs 15 repeatedly aligned in two dimensions are formed inside the lower insulating layer 13. The storage contact plugs 15 may be formed using a typical self-aligned contact technology. The storage contact plugs 15 may be aligned on the semiconductor substrate 11 in a square-lattice pattern shape, like the concentric circles as shown in FIG. 1B.

Referring to FIGS. 1A, 1B, and 2B, an etch barrier layer 17, a lower sacrificial oxide layer 19, and a holding material layer 21 are sequentially formed on the semiconductor substrate having the storage contact plugs 15. The etch barrier layer 17 may be formed of a silicon nitride layer. The lower sacrificial oxide layer 19 may be formed of a spin-on-glass (SOG) or a silicon oxide layer such as an undoped silicate glass(USG). The holding material layer 21 may be formed of a non-conductive material layer having a low etch rate for a wet etch recipe of the lower sacrificial oxide layer 19, with a thickness of 100 Å to 1000 Å. The non-conductive material layer may be an SiN or SiC layer.

Referring to FIGS. 1A, 1B, and 2C, a photoresist layer is formed on the holding material layer 21. The photoresist layer is patterned to form a photoresist pattern having openings exposing the holding material layer 21. Since the holding material layer 21 is relatively thin in thickness, the photoresist layer may be also formed thin. Thus, it is easy to pattern the photoresist layer. Further, if necessary, the photoresist pattern may be isotropically etched using oxygen plasma to expand the openings exposing the holding layer 21.

The holding material layer 21 is etched using the photoresist pattern as an etch mask to form a holding layer 21a having openings 21b exposing the lower sacrificial oxide layer 19. The openings 21b shown as a dotted line in FIG. 2C represent the rear openings in the back shown in the sectional view taken along the line I-I of FIG. 1A.

The centers of the respective openings 21b are located above portions of the lower insulating layer 13 that are surrounded by the storage contact plugs 15 which are repeatedly aligned in two dimensions.

Referring to FIGS. 1A, 1B, and 2D, an upper sacrificial oxide layer 23 is formed over the semiconductor substrate having the holding layer 21a with the openings 21b. The upper sacrificial oxide layer 23 can be formed of a silicon oxide layer like the lower sacrificial oxide layer 19. After the upper sacrificial oxide layer 23 is formed, the upper sacrificial oxide layer 23 may be planarized by using CMP technology.

Referring to FIGS. 1A, 1B, and 2E, the upper sacrificial oxide layer 23, the holding layer 21a having the openings 21b, the lower sacrificial oxide layer 19, and the etch barrier layer 17 are sequentially patterned using photolithography and etch processes, to form capacitor holes 25 exposing the storage contact plugs 15 and holding layer patterns 21c. The holding layer patterns 21c are exposed inside the capacitor holes 25.

The holding material layer 21 is formed of a different material layer from the upper sacrificial oxide layer 23 and the lower sacrificial oxide layer 19. Thus, it is preferable to perform an etch process by separating the step of etching the upper sacrificial oxide layer 23 and the holding layer 21a, and the step of etching the lower sacrificial oxide layer 19. That is, in the step of etching the upper sacrificial oxide layer 23 and the holding layer 21a, an etch recipe for providing similar etch rate of the upper sacrificial oxide layer 23 and the holding material layer 21 is used. As a result, etching of the lower sacrificial oxide layer 19 may be minimized until the holding layer patterns 21c are formed. Then, the lower sacrificial oxide layer 19 is etched using an etch recipe so that the lower sacrificial oxide layer 19 is etched at a relatively high rate compared to the etch barrier layer 17. As such, the capacitor holes 25 can be formed quickly without damage to the storage contact plugs 15.

Referring to FIGS. 1B and 2F, a lower plate conductive layer 25 is conformally formed on the semiconductor substrate having the capacitor holes 25. The lower plate conductive layer 25 may be a poly silicon layer or a metal layer. The lower plate conductive layer 25 contacts the holding layer patterns 21c. A filling layer 27 filling the capacitor holes 25 is formed on the semiconductor substrate having the lower plate conductive layer 25. The filling layer 27 may be etched back to expose the lower plate conductive layer 25.

Referring to FIGS. 1B and 2G, the filling layer 27 and the lower plate conductive layer 25 are planarized until the top surface of the upper sacrificial oxide layer 23 is exposed, to form lower plates 25a separated from each other. Then, the filling layer 27 remaining inside the capacitor holes 25 is removed. The process of planarizing the lower plate conductive layer 25 and the filling layer 27 can be performed using an etch back technology or a CMP technology.

Referring to FIGS. 1B and 2H, after the lower plates 25a are formed, the upper sacrificial oxide layer 23 and the lower sacrificial oxide layer 19 are removed using a wet etch process. The upper sacrificial oxide layer 23 and the lower sacrificial oxide layer 19 may be removed along with the filling layer 27. Since the holding layer patterns 21c are formed of a material layer having a low etch rate for wet etch recipes of the upper sacrificial oxide layer 23 and the lower sacrificial oxide layer 19, they are not removed. Therefore, the holding layer patterns 21c are located between the uppermost portions of the lower plates 25a and the lowermost portions of the lower plates 25a to connect the side walls of the adjacent lower plates 25a, and function to support the lower plates 25a. As a result, a leaning phenomenon of the lower plates 25a can be avoided.

In the meantime, with the removal of the lower sacrificial oxide layer 19 and the upper sacrificial oxide layer 23, the etch barrier layer 17 is exposed between the lower plates 25. The etch barrier layer 17 prevents the lower insulating layer 13 from being etched during the wet etch process.

Referring to FIGS. 1B and 2I, a capacitor dielectric layer 27 is formed on the semiconductor substrate after the upper sacrificial oxide layer 23 and the lower sacrificial oxide layer 19 are removed. The capacitor dielectric layer 27 conformally covers the inner surface and the outer surface of the respective lower plates 25a. The capacitor dielectric layer 27 can be formed using chemical vapor deposition (CVD) or atomic layer deposition (ALD) technology.

An upper plate conductive layer is formed on the semiconductor substrate having the capacitor dielectric layer 27, and is then patterned to form an upper plate 29. The upper plate conductive layer may be formed of a polysilicon layer or a metal layer, and may be formed using CVD or ALD technology. As a result, the formation of a plurality of capacitors employing the holding layer patterns 21c is completed.

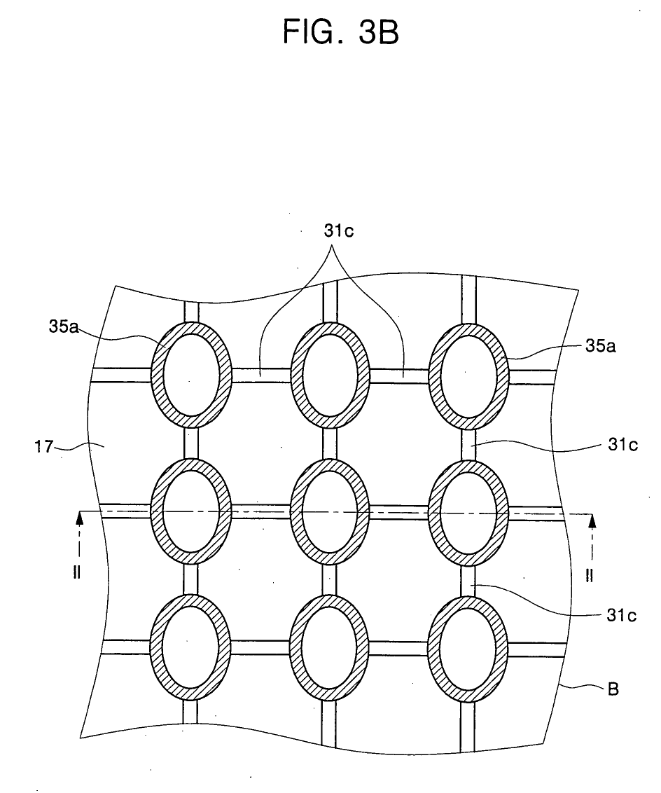

FIGS. 3A and 3B are top plan views illustrating another plurality of capacitors fabricated according to processing sequences of one embodiment of the present invention. In FIGS. 3A and 3B, the reference letter “B” represents the same area on the semiconductor substrate, and FIGS. 2A to 2I can be referred to as the sectional views taken along the line II-II of FIGS. 3A and 3B.

Referring to FIGS. 3A and 3B, in the same way as described with reference to FIG. 2A, a semiconductor substrate 11 of FIG. 2A having a lower insulating layer 13 of FIG. 2A is prepared, and storage contact plugs 15 of FIG. 2A is formed inside the lower insulating layer 13. However, the storage contact plugs 15, like ovals as shown in FIG. 3B, are aligned in a orthogonal-lattice pattern shape. Then, as described with reference to FIG. 2B, an etch barrier layer 17, a lower sacrificial oxide layer 19, and a holding material layer 21 are formed.

The holding material layer 21 is patterned to form a holding layer 31a having oval-shaped openings 31b as shown in FIG. 3A. The centers of the respective openings 31b are located over portions of the lower insulating layer 13 that are surrounded by the storage contact plugs 15, and the process of patterning the holding layer 31a is the same as illustrated with reference to FIG. 2C.

As illustrated with reference to FIG. 2D, an upper sacrificial oxide layer 23 is formed over the semiconductor substrate having the holding layer 31a. Then, as illustrated with reference to FIG. 2E, there are formed capacitor holes 25 of FIG. 2E exposing the storage contact plugs 15. However, the horizontal section of the respective capacitor holes 25 is oval in shape. Herein, holding layer patterns 31c as shown in FIG. 3B are also formed.

Then, as illustrated with reference to FIGS. 2F to 21, lower plates 35a, a capacitor dielectric layer 27, and an upper plate 29 are formed. However, the horizontal section of the respective lower plates 35a is oval in shape unlike the lower plates 25a as shown in FIG. 1B. As such, a plurality of capacitors having major axis and minor axis are formed.

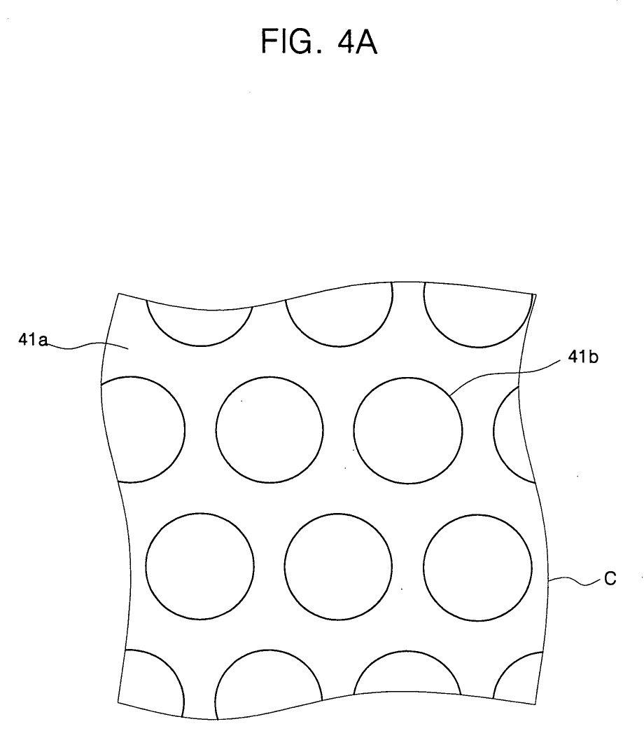

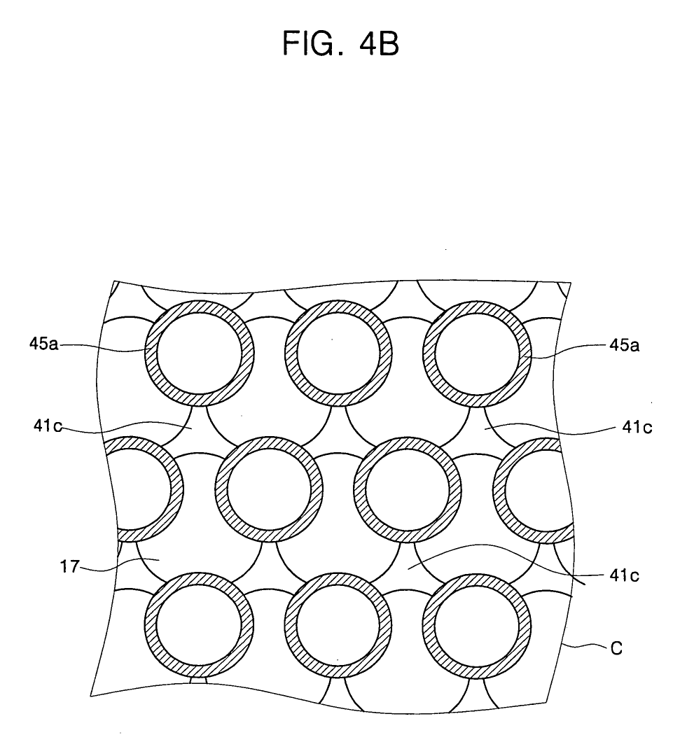

FIGS. 4A and 4B are top plan views illustrating a further plurality of capacitors fabricated according to processing sequences of one embodiment of the present invention. In FIGS. 4A and 4B, the reference letter “C” represents a same area on a semiconductor substrate.

Referring to FIGS. 4A and 4B, processing sequences and material layers are the same as described in reference to FIGS. 2A to 21. However, each of the storage contact plugs 15 of FIG. 2A is aligned to have six other adjacent storage contact plugs 15 like the concentric circles as shown in FIG. 4B. Thus, the holding material layer 21 of FIG. 2B is patterned to form a holding layer 41c having openings 41b as shown in FIG. 4A. Each of the openings 41b has six other adjacent openings 41b. Further, since the capacitor holes 25 of FIG. 2E exposing the storage contact plugs 15 are aligned in the same way as the storage contact plugs 15, each of the capacitor holes 25 has six adjacent capacitor holes 25. In the meantime, each of the holding layer patterns 41c, which are formed during the formation of the capacitor holes 25, is exposed to the side walls of the three adjacent capacitor holes 25. Lower plates 45a are formed on the side walls of the capacitor holes 25. Each of the lower plates 45a has six other adjacent lower plates 45a. Further, each of the holding layer patterns 41c is connected to three adjacent lower plates 45a to support the lower plates 45a.

Hereinafter, the structure of a plurality of capacitors according to another embodiment of the present invention will be described in detail with reference to FIGS. 1B, 2I, 3B, and 4B.

Referring to FIGS. 1B and 2I, a plurality of cylinder-shaped lower plates 25a are repeatedly aligned in two dimensions on a same plane over the semiconductor substrate 11. The horizontal section of the cylinder-shaped lower plates 25a is not limited to a circular shape, and may be an oval shape as shown in FIG. 3B. Further, each of the plurality of the cylinder-shaped lower plates 25a may be aligned to have four other adjacent lower plates 25a, but as shown in FIG. 4B, may be aligned to have six other adjacent lower plates.

Holding layer patterns 21c connect the adjacent side walls of the lower plates 25a. The holding layer patterns 21c are located between the uppermost portions and the lowermost portions of the lower plates 25a. In the meantime, the holding layer patterns 21c are formed of a non-conductive material layer, and preferably have a thickness of 100 Å to 1000 Å.

Each of the holding layer patterns 21c may connect two adjacent lower plates 25a or 35a as shown in FIGS. 1B and 3B, or may connect three adjacent lower plates 45a as shown in FIG. 4B.

In the meantime, an upper plate 29 fills the spaces inside and between the side walls of the lower plates 25a. Further, a capacitor dielectric layer 27 is interposed between the lower plates 25a and the upper plate 29 to insulate the lower plates 25a and the upper plate 29.

In the meantime, storage contact plugs 15 are interposed between the semiconductor substrate 11 and the lower plates 25a to electrically connect the semiconductor substrate 11 and the respective lower plates 25a.

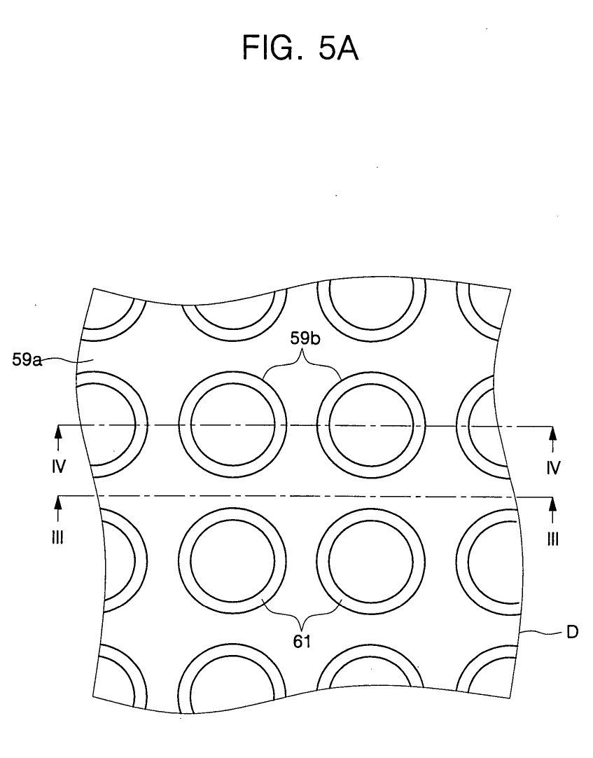

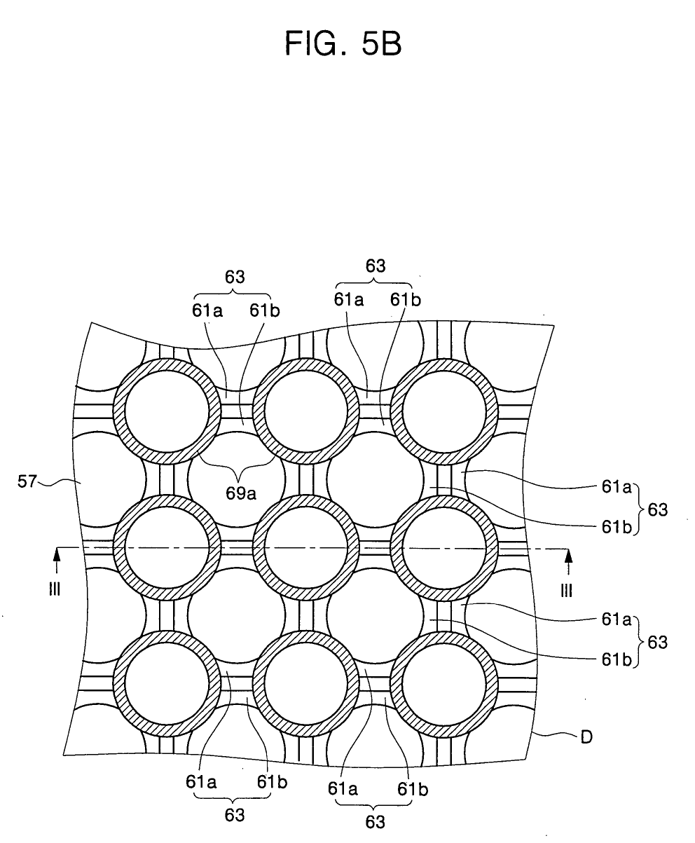

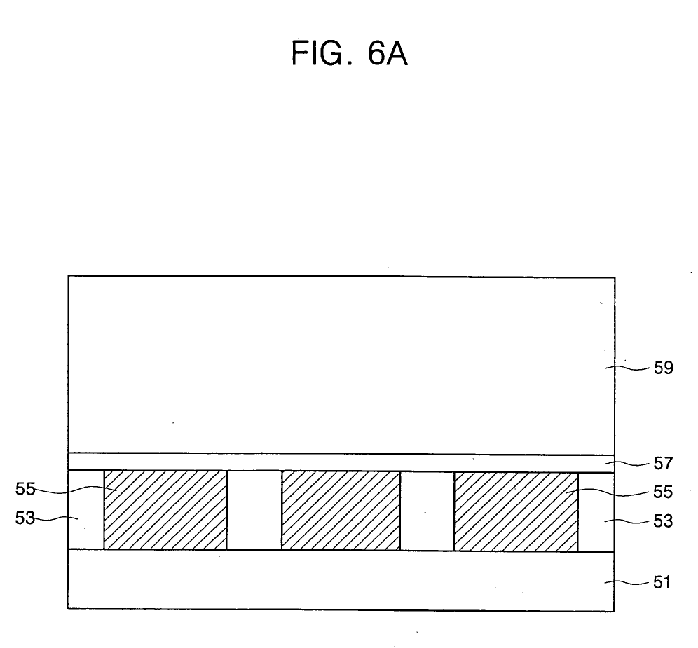

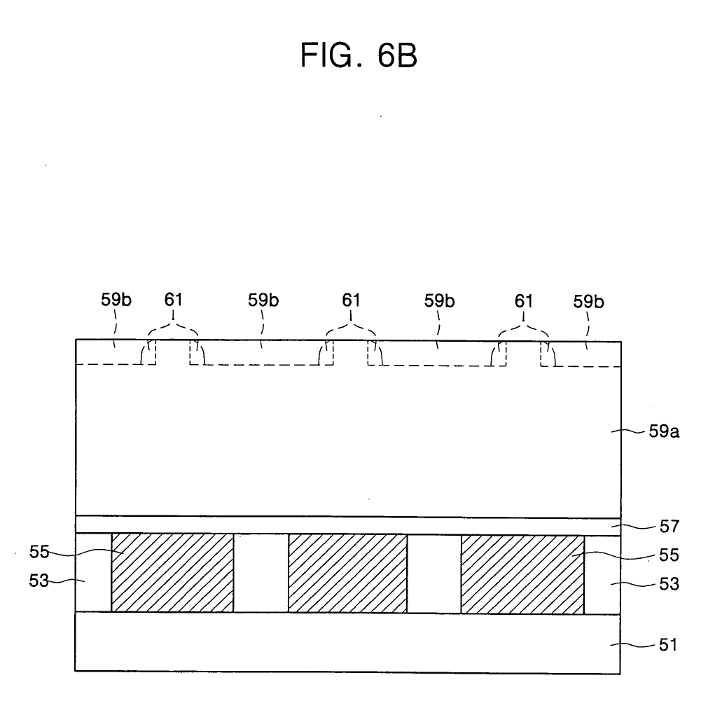

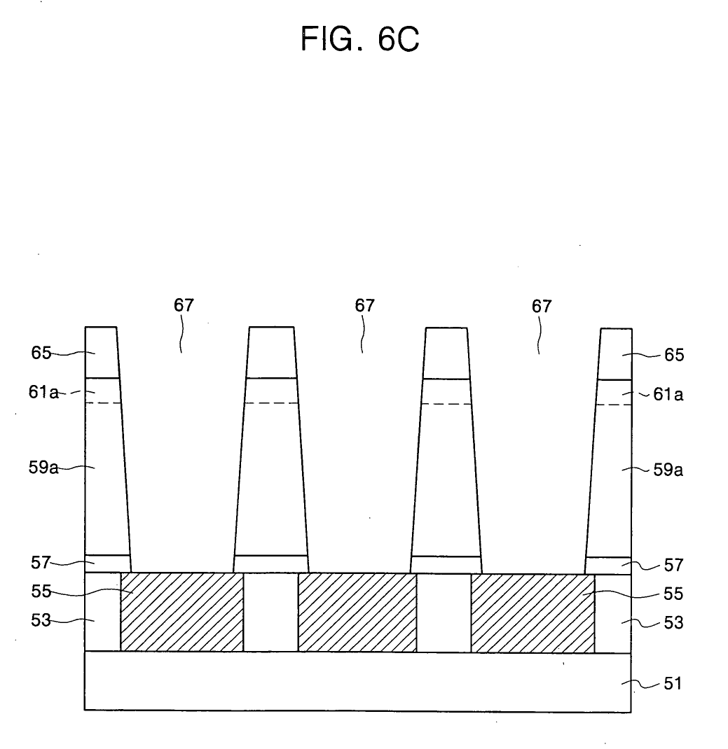

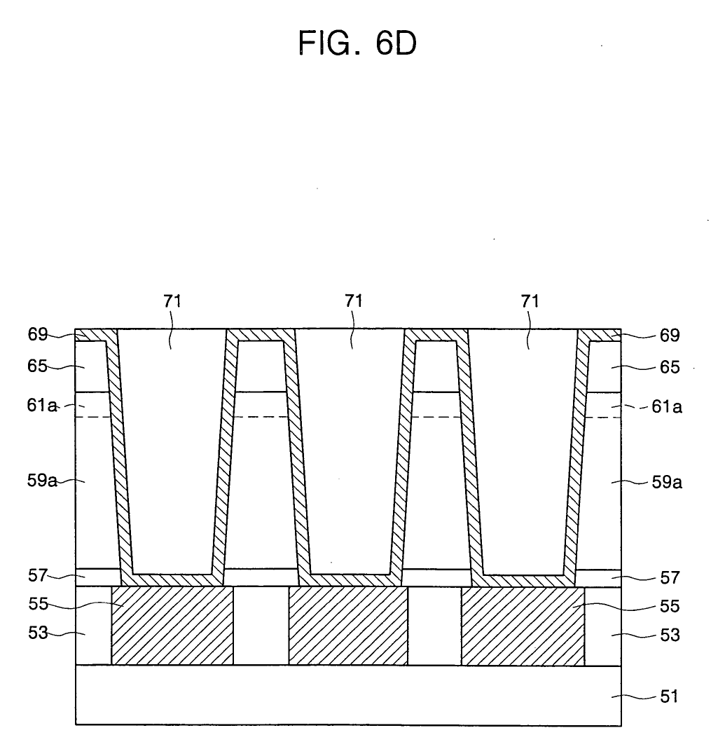

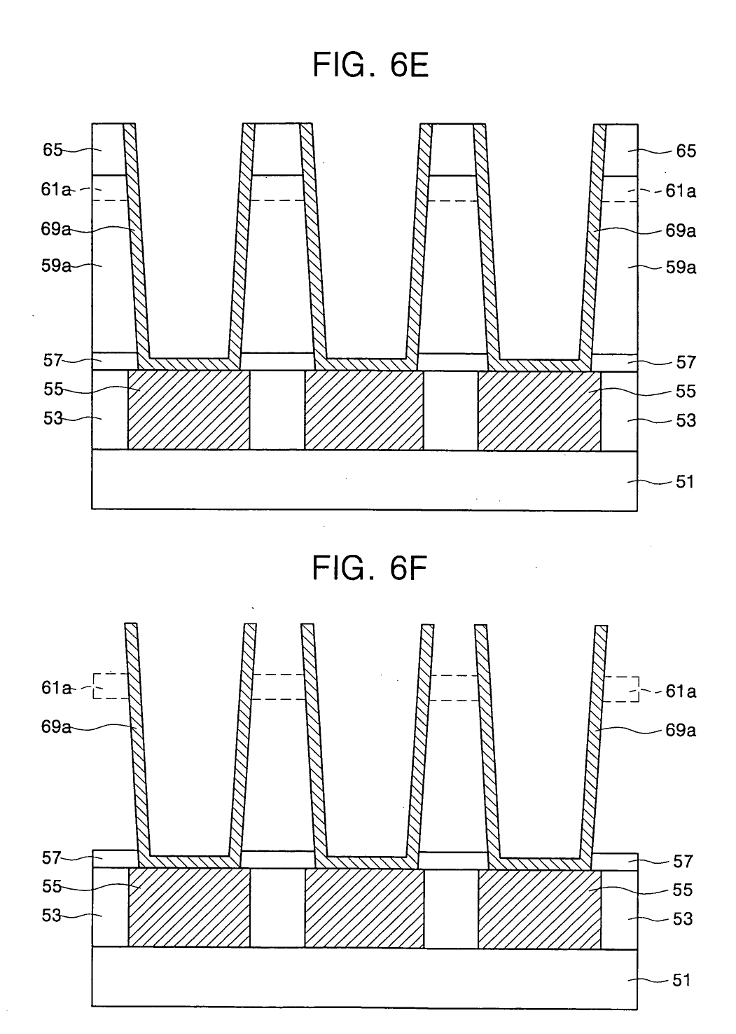

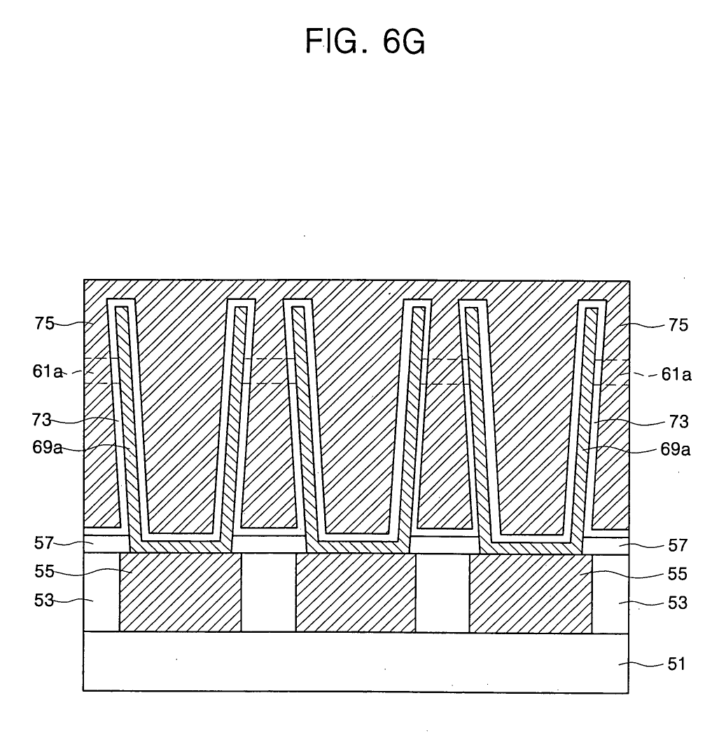

FIGS. 5A and 5B are top plan views respectively showing a lower sacrificial oxide layer having spacers, and a plurality of lower plates to illustrate a method of fabricating a plurality of capacitors according to another embodiment of the present invention, and FIGS. 6A to 6G are sectional views illustrating a method of fabricating a plurality of capacitors according to another embodiment of the present invention taken along the line III-III of FIGS. 5A and 5B. The dotted line of FIG. 6B shows a partial section of the lower sacrificial oxide layer 59a taken along the line IV-IV of FIG. 5A. In FIGS. 5A and 5B, the reference letter “D” represents a same area on a semiconductor substrate.

Referring to FIGS. 5A, 5B, and 6A, a semiconductor substrate 51 having a lower insulating layer 53 is prepared. Transistors (not shown) and bit lines (not shown) may be formed on the semiconductor substrate. The lower insulating layer 53 electrically insulates the transistors and the bit lines from a plurality of capacitors to be formed.

Storage contact plugs 55 repeatedly aligned in two dimensions are formed inside the lower insulating layer 53. The storage contact plugs 55 may be formed using atypical self-aligned contact technology. The storage contact plugs 55 may be aligned on the semiconductor substrate 51 in a square-lattice pattern shape, like the concentric circles as shown in FIG. 5B.

An etch barrier layer 57 and a lower sacrificial oxide layer 59 are sequentially formed over the semiconductor substrate having the storage contact plugs 55. The etch barrier layer 57 may be formed of a silicon nitride layer. The lower sacrificial oxide layer 59 may be formed of a spin-on-glass (SOG) or a silicon oxide layer such as an undoped silicate glass (USG).

Referring to FIGS. 5A, 5B, and 6B, a photoresist layer is formed on the lower sacrificial oxide layer 59. The photoresist layer is patterned to form a photoresist pattern having openings exposing the lower sacrificial oxide layer 59. The lower sacrificial oxide layer 59 is partially etched using the photoresist pattern as an etch mask to form a lower sacrificial oxide layer 59a having grooves 59b. Herein, the lower sacrificial oxide layer 59 may be partially etched to a depth of 500 Å to 2000 Å. Herein, the dotted line shown in FIG. 6B represents a partial section of the lower sacrificial oxide layer 59a taken along the line IV-IV of FIG. 5A. The centers of the respective grooves 59b are located over the lower insulating layer 53 that is surrounded by the storage contact plugs 55.

A spacer layer is formed on the lower sacrificial oxide layer 59a having the grooves 59b. The spacer layer is formed of a non-conductive material layer having a low etch rate for a wet etch recipe of the lower sacrificial oxide layer 59. The non-conductive material layer may be an SiN or SiC layer. The spacer layer is etched back to form spacers 61 covering side walls of the grooves 59b. Thus, the respective spacers 61 have a tapered shape, the lower sides of which are wide, and the upper sides of which are narrow.

Referring to FIGS. 5A, 5B, and 6C, an upper sacrificial oxide layer 65 is formed over the semiconductor substrate having the spacers 61. The upper sacrificial oxide layer 65 may be formed of a silicon oxide layer like the lower sacrificial oxide layer 59. The upper sacrificial oxide layer 65 fills the grooves 59b in which the spacers 61 are formed. After the upper sacrificial oxide layer 65 is formed, the upper sacrificial oxide layer 65 may be planarized using a CMP technology.

The upper sacrificial oxide layer 65, the spacers 61, the lower sacrificial oxide layer 59a, and the etch barrier layer 57 are sequentially patterned using photolithography and etch processes, to form capacitor holes 67 exposing the storage contact plugs 55 and holding layer patterns 63. Herein, each of the holding layer patterns 63 comprises a pair of etched spacers 61a, 61b, which are formed while the capacitor holes 67 are formed, and the holding layer patterns 63 are exposed inside the capacitor holes 25.

In the meantime, the etched spacers 61a shown in FIG. 6C represent the etched spacers 61a, which are located in the back of the section taken along the line III-III of FIG. 5B.

The spacers 61 are formed of a different material layer from the upper sacrificial oxide layer 65 and the lower sacrificial oxide layer 59. Thus, as described with reference to FIG. 2E, it is preferable to perform an etch process by separating the step of etching the upper sacrificial oxide layer 65 and the spacers 61, and the step of etching the lower sacrificial oxide layer 59.

Referring to FIGS. 5B and 6D, a lower plate conductive layer 69 is conformally formed on the semiconductor substrate having the capacitor holes 67. The lower plate conductive layer 69 may be a polysilicon layer or a metal layer. The lower plate conductive layer 69 contacts the holding layer patterns 63. A filling layer 71 filling the capacitor holes 67 is formed over the semiconductor substrate having the lower plate conductive layer 69. The filling layer 71 is etched back to expose the lower plate conductive layer 69.

Referring to FIGS. 5B and 6E, the filling layer 71 and the lower plate conductive layer 69 are planarized until the top surface of the upper sacrificial oxide layer 65 is exposed, to form lower plates 69a separated from each other. Then, the filling layer 71 remaining inside the capacitor holes 67 is removed. The process of planarizing the lower plate conductive layer 69 and the filling layer 71 may be performed using an etch back or a CMP process.

Referring to FIGS. 5B and 6F, after the lower plates 69a are formed, the upper sacrificial oxide layer 65 and the lower sacrificial oxide layer 59 are removed using a wet etch process. The upper sacrificial oxide layer 65 and the lower sacrificial oxide layer 59 may be removed along with the filling layer 71. Since the holding layer patterns 63 are formed of a material layer having a low etch rate for wet etch recipe of the upper sacrificial oxide layer 65 and the lower sacrificial oxide layer 59, they are not removed. Therefore, the holding layer patterns 63 are located between the uppermost portions and the lowermost portions of the lower plates 69a to connect the side walls of the adjacent lower plates 69a, and function to support the lower plates 69a. As a result, a leaning phenomenon of the lower plates 69a can be avoided.

In the meantime, with the removal of the lower sacrificial oxide layer 59 and the upper sacrificial oxide layer 65, the etch barrier layer 57 is exposed between the lower plates 69a. The etch barrier layer 57 prevents the lower insulating layer 53 from being etched during the wet etch process.

Referring to FIGS. 5B and 6G, a capacitor dielectric layer 73 is formed on the semiconductor substrate from which the upper sacrificial oxide layer 65 and the lower sacrificial oxide layer 59 are removed. The capacitor dielectric layer 73 conformally covers the inner surface and the outer surface of the respective lower plates 69a. The capacitor dielectric layer 73 may be formed using CVD or ALD technology.

An upper plate conductive layer is formed over the semiconductor substrate having the capacitor dielectric layer 73, and it is patterned to form an upper plate 75. The upper plate conductive layer may be formed of a polysilicon layer or a metal layer, and may be formed using CVD or ALD technology. As a result, a plurality of capacitors employing the holding layer patterns 63 are formed.

As a result, each of the holding layer patterns 63 comprises a pair of etched spacers 61a, 61b. Since the etched spacers 61a, 61b have inclined shapes, it is easy to form the capacitor dielectric layer 73 and the upper plate conductive layer between the lower plates 69a. Thus, the etched spacers 61a, 61b can be formed relatively high, so that they can support the lower plates 69a relatively firmly.

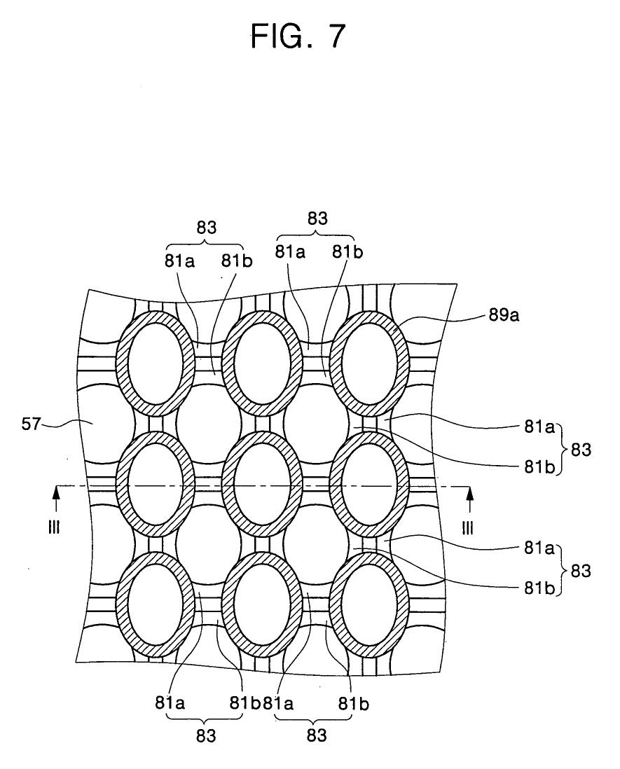

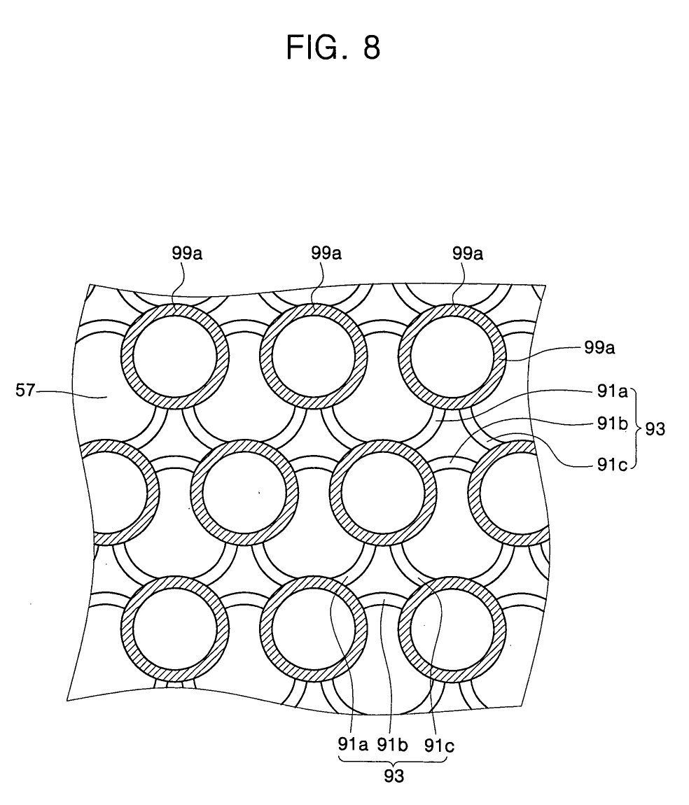

FIGS. 7 and 8 are top plan views illustrating a plurality of various capacitors fabricated according to processing sequences of another embodiment of the present invention.

Referring to FIG. 7, process sequences, material layers or the like are the same as illustrated in reference to FIGS. 6A to 6G. However, the storage contact plugs 55 of FIG. 6A are ovals in shape as shown in FIG. 7, and are aligned in a rectangular-lattice pattern shape. Thus, the openings, which are formed by partially etching the lower sacrificial oxide layer 59 of FIG. 6A, are also ovals and formed to be aligned in a rectangular-lattice pattern shape. Further, the capacitor holes 67 of FIG. 6C exposing the storage contact plugs 55 are aligned in the same way as the storage contact plugs 55. In the meantime, each of the holding layer patterns 83, which are also formed during the formation of the capacitor holes 67, comprises a pair of etched spacers 81a, 81b, which are formed in the same way as the holding layer patterns 61 of FIG. 5B.

The lower plates 89a, which are formed inside the capacitor holes 67, are formed such that the horizontal section of each lower plate is oval-shaped. Further, each of the holding layer patterns 83 is connected to the adjacent lower plates 89a, and supports the lower plates 89a.

Referring to FIG. 8, process sequences and material layers are the same as illustrated in reference to FIGS. 6A to 6G. However, each of the storage contact plugs 55 of FIG. 6A is aligned to have six adjacent storage contact plugs 55 like the concentric circles as shown in FIG. 8. Thus, each of the grooves 59b of FIG. 6B is aligned to have six other adjacent grooves 59b. Further, since the capacitor holes 67 of FIG. 6C exposing the storage contact plugs 55 are aligned in the same way as the storage contact plugs 55, each of the capacitor holes 67 has six other adjacent capacitor holes 67. In the meantime, each of the holding layer patterns 93, which are also formed during the formation of the capacitor holes 67, comprises a pair of etched spacers 91a, 91b, 91c. Each of the etched spacers 91a, 91b, 91c is exposed to the side walls of the two adjacent capacitor holes 67 at the same time. Since the lower plates 99a are formed on the inner walls of the capacitor holes 67, each of the lower plates 99a has six other adjacent lower plates 99a. Further, each of the etched spacers 91a, 91b, 91c is connected to the two adjacent lower plates 99a to support the lower plates 99a.

Now hereinafter, the structure of a plurality of capacitors according to another embodiment of the present invention will be described in detail in reference to FIGS. 5B, 6G, 7 and 8.

Referring to FIGS. 5B and 6G, a plurality of cylinder-shaped lower plates 69a are repeatedly aligned in two dimensions on a same plane over the semiconductor substrate 51. The horizontal section of the cylinder-shaped lower plates 69a is not limited to a circular shape, and may be an oval shape as shown in FIG. 7.

Further, each of the plurality of the cylinder-shaped lower plates 69a may be aligned to have four adjacent lower plates 69a, or as shown in FIG. 8, may be aligned to have six other adjacent lower plates.

Holding layer patterns 63 connect the adjacent side walls of the lower plates 69a. Each of the holding layer patterns 63 may comprise a pair of two etched spacers 61a, 61b which are spaced from and face to each other. However, each of the holding layer patterns 63 may comprise a pair of three etched spacers 91a, 91b, 91c as shown in FIG. 8. At this time, each of the etched spacers 91a, 91b, 91c connects two adjacent lower plates 99a, and each of the holding layer patterns 93 connects three adjacent lower plates 99a.

The holding layer patterns 63 are located between the uppermost portions and the lowermost portions of the lower plates 69a. In the meantime, the etched spacers 61a, 61b are formed of a non-conductive material layer, and preferably have a thickness of 500 Å to 2000 Å.

In the meantime, the upper plate 75 fills the spaces inside and between the side walls of the lower plates 69a. A capacitor dielectric layer 73 is interposed between the lower plates 69a and the upper plate 75, and insulates the lower plates 69a and the upper plate 75.

In the meantime, storage contact plugs 55 are interposed between the semiconductor substrate 51 and the lower plates 69a, and electrically connect the semiconductor substrate 51 and each of the lower plates 69a.

According to the present invention, there are provided a plurality of capacitors employing holding layer patterns so as to obtain sufficient capacitance and avoid the leaning phenomenon of the lower plates, and there is provided a semiconductor device having the plurality of capacitors. Further, there is provided a method of fabricating the plurality of capacitors capable of avoiding the leaning phenomenon of the lower plates by employing holding layer patterns.

1. A plurality of capacitors comprising:
a plurality of cylinder-shaped lower plates repeatedly aligned in two dimensions;
holding layer patterns located between uppermost portions and lowermost portions of the plurality of cylinder-shaped lower plates, and connecting adjacent side walls of the plurality of cylinder-shaped lower plates;
an upper plate filling spaces inside the plurality of cylinder-shaped lower plates and spaces between the adjacent side walls; and
a capacitor dielectric layer interposed between the plurality of cylinder-shaped lower plates and the upper plate, and insulating the plurality of cylinder-shaped lower plates and the upper plate.

2. The plurality of capacitors according to claim 1, wherein the holding layer patterns are formed of a non-conductive material layer.

3. The plurality of capacitors according to claim 2, wherein each of the plurality of cylinder-shaped lower plates aligned in two dimensions is aligned to have four adjacent lower plates.

4. The plurality of capacitors according to claim 3, wherein the holding layer patterns have a thickness of 100 Å to 1000 Å.

5. The plurality of capacitors according to claim 4, wherein the non-conductive material layer is one material layer selected from the group consisting of SiN and SiC.

6. The plurality of capacitors according to claim 5, wherein the horizontal section of each of the plurality of cylinder-shaped lower plates has oval shape.

7. The plurality of capacitors according to claim 2, wherein each of the plurality of cylinder-shaped lower plates aligned in two dimensions is aligned to have six adjacent cylinder-shaped lower plates.

8. The plurality of capacitors according to claim 7, wherein each of the holding layer patterns connects three adjacent cylinder-shaped lower plates.

9. The plurality of capacitors according to claim 2, wherein each of the holding layer patterns comprises a pair of elements, which are spaced and face each other.

10. The plurality of capacitors according to claim 9, wherein each of the holding layer patterns is a pair of etched spacers, lower sides of which are wide and upper sides of which are narrow.

11. The plurality of capacitors according to claim 10, wherein the etched spacers have a height of 500 Å to 2000 Å.

12. A semiconductor device comprising:
a semiconductor substrate;
a plurality of cylinder-shaped lower plates repeatedly aligned in two dimensions over the semiconductor substrate;
holding layer patterns located between uppermost portions and lowermost portions of the plurality of cylinder-shaped lower plates, and connecting adjacent side walls of the plurality of cylinder-shaped lower plates;
an upper plate filling spaces inside the plurality of cylinder-shaped lower plates and spaces between the adjacent side walls thereof; and
a capacitor dielectric layer interposed between the plurality of cylinder-shaped lower plates and the upper plate, and insulating the plurality of cylinder-shaped lower plates and the upper plate.

13. The semiconductor device according to claim 12, further comprising:
storage contact plugs interposed between the semiconductor substrate and each of the plurality of cylinder-shaped lower plates, and connecting the semiconductor substrate and each of the plurality of cylinder-shaped lower plates.

14. A method of fabricating a plurality of capacitors comprising:
preparing a semiconductor substrate having a lower insulating layer;
forming a plurality of storage contact plugs repeatedly aligned in two dimensions inside the lower insulating layer;
sequentially forming an etch barrier layer and a lower sacrificial oxide layer on the lower insulating layer and the storage contact plugs;
forming a holding layer on the lower sacrificial oxide layer, the holding layer having openings exposing the lower sacrificial oxide layer, centers of the openings being located above respective portions of the lower insulating layer that are surrounded by the storage contact plugs;
forming an upper sacrificial oxide layer over the holding layer and the openings;
sequentially patterning the upper sacrificial oxide layer, the holding layer, the lower sacrificial oxide layer, and the etch barrier layer using photolithography and etch processes, to form capacitor holes exposing the storage contact plugs and holding layer patterns exposed inside the capacitor holes;
forming lower plates covering inner walls of the capacitor holes; and
removing the upper sacrificial oxide layer and the lower sacrificial oxide layer between the lower plates.

15. The method according to claim 14, wherein said forming a holding layer comprises:
forming a holding material layer on the lower sacrificial oxide layer;
forming a photoresist layer on the holding material layer;
patterning the photoresist layer to form a photoresist pattern having openings exposing the holding material layer; and
etching the holding material layer using the photoresist pattern as an etch mask.

16. The method according to claim 15, wherein the holding material layer is a non-conductive material layer having a low etch rate for wet etch recipes of the lower sacrificial oxide layer and the upper sacrificial oxide layer.

17. The method according to claim 16, wherein the non-conductive material layer has a thickness of 100 Å to 1000 Å.

18. The method according to claim 17, wherein the non-conductive material layer is at least one material layer selected from the group consisting of SiN and SiC.

19. The method according to claim 14, wherein said forming lower plates comprises:
forming a lower plate conductive layer on remaining portions of the upper sacrificial oxide layer and in the capacitor holes;
forming a filling layer filling the capacitor holes having the lower plate conductive layer formed thereon; and
planarizing the filling layer and the lower plate conductive layer until a top surface of the upper sacrificial oxide layer is exposed.

20. The method according to claim 19, further comprising:
forming a conformal capacitor dielectric layer on the lower plates and the holding layer patterns, after said removing the upper sacrificial oxide layer and the lower sacrificial oxide layer; and
forming an upper plate covering the capacitor dielectric layer to fill spaces inside the capacitor holes and spaces between side walls of the lower plates.

21. A method of fabricating a plurality of capacitors comprising:
preparing a semiconductor substrate having a lower insulating layer;
forming a plurality of storage contact plugs repeatedly aligned in two dimensions inside the lower insulating layer;
sequentially forming an etch barrier layer and a lower sacrificial oxide layer on the lower insulating layer and the storage contact plugs;
partially etching the lower sacrificial oxide layer to form grooves repeatedly aligned in two dimensions, centers of the grooves being located above respective portions of the lower insulating layer that are surrounded by the storage contact plugs;
forming spacers covering inner walls of the grooves;
forming an upper sacrificial oxide layer on the lower sacrificial oxide layer and the spacers;
patterning the upper sacrificial oxide layer, the spacers, the lower sacrificial oxide layer, and the etch barrier layer using photolithography and etch processes, to form capacitor holes exposing the storage contact plugs, and the spacers as holding layer patterns exposed inside the capacitor holes;
forming lower plates covering inner walls of the capacitor holes; and
removing the upper sacrificial oxide layer and the lower sacrificial oxide layer between the lower plates.

22. The method according to claim 21, wherein the lower sacrificial oxide layer is partially etched to a depth of 500 Å to 2000 Å.

23. The method according to claim 22, wherein the spacers are formed of a non-conductive material layer having a low etch rate for wet etch recipes of the upper sacrificial oxide layer and the lower sacrificial oxide layer.

24. The method according to claim 23, wherein the non-conductive material one material layer selected from the group consisting of SiN and SiC.
